(19) United States
(12) Patent Application Publication
(10) Pub. No.: US 2019/0006259 A1
(43) Pub. Date: Jan. 3, 2019

(54) COOLING SOLUTION DESIGNS FOR MICROELECTRONIC PACKAGES

(71) Applicant: Intel Corporation, Santa Clara, CA (US)

(72) Inventors: Dinesh Padmanabhan Ramalekshmi Thanu, Chandler, AZ (US); Wei Hu, Chandler, AZ (US); James C. Matayabas, JR., Gilber, AZ (US); Baris Bicen, Chandler, AZ (US); Luke J. Garner, Chandler, AZ (US); Hemanth Dhavaleswarapu, Chandler, AZ (US)

(73) Assignee: Intel Corporation, Santa Clara, CA (US)

(21) Appl. No.: 15/637,107

(22) Filed: Jun. 29, 2017

(51) Int. Cl. H01L 23/367; H01L 25/065; H01L 23/00

(52) U.S. Cl. CPC H01L 23/367; H01L 24/83; H01L 24/33; H01L 25/0655

(57) ABSTRACT

Methods of forming microelectronic package structures/modules, and structures formed thereby, are described. Structures formed herein may include a first die disposed on a substrate and a second die disposed adjacent the first die on the substrate. A cooling solution is attached to the substrate, wherein a rib extends from a central region of the cooling solution and is attached to the substrate. The rib is disposed between the first die and the second die.

### BACKGROUND

Ever increasing communication frequencies and larger memory access bandwidth are leading to increased package integration. Microelectronic packages are housing multiple die within the same package, such as memory die adjacent to microprocessor die, transceiver devices, field programmable gate arrays (FPGA) and even other microprocessor die, on a single substrate. Complex multi-chip packages (MCP) present challenges for thermal interface materials (TIM), such as die to die height variations, that can cause variations in TIM thickness, which may in turn lead to TIM stress and degradation. Such thermal challenges may induce stress of the TIM at die to die boundary regions, for example.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIGS. 1a-1e represents top views of structures according to embodiments.

FIGS. 2a-2c represent cross-sectional views of structures formed according to methods of forming package structures according to embodiments.

FIG. 3 represents a flowchart of a method of forming package structures according to embodiments.

FIG. 4 represents a cross section of a portion of a computing system according to embodiments.

FIG. 5 represents a schematic of a computing system according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between an electrical component, such a an integrated circuit (IC) die, and a next-level component to which an IC package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die may include a front-side and an opposing back-side. In some embodiments, the front-side may be referred to as the “active surface” of the die. A number of interconnects may extend from the die's front-side to the underlying substrate, and these interconnects may electrically couple the die and substrate. In some cases a die may be directly coupled to a board, such as a motherboard. Interconnects/traces may comprise any type of structure and materials capable of providing electrical communication between a die and substrate/board. In one embodiment, a die may be disposed on a substrate in a flip-chip arrangement. In an embodiment interconnects comprise an electrically conductive terminal on a die (e.g., a pad, bump, stud bump, column, pillar, or other suitable structure or combination of structures) and a corresponding electrically conductive terminal on the substrate (e.g., a pad, bump, stud bump, column, pillar, or other suitable structure or combination of structures).

Solder (e.g., in the form of balls or bumps) may be disposed on the terminals of the substrate and/or die, and these terminals may then be joined using a solder reflow process. Of course, it should be understood that many other types of interconnects and materials are possible (e.g., wirebonds extending between a die and substrate). In some embodiments herein, a die may be coupled with a substrate by a number of interconnects in a flip-chip arrangement. However, in other embodiments, alternative structures and/or methods may be utilized to couple a die with a substrate.

Embodiments of methods of forming packaging structures, including methods of forming cooling solution structures for stress reduction and thermal property enhancements, are described. Those structures formed thereby may include a package structure comprising a first die disposed on a substrate and a second die disposed adjacent the first die on the substrate. A cooling solution is attached to the substrate, wherein a rib extends from a central region of the cooling solution, and is attached to the substrate. The rib may be disposed between the first die and the second die. The embodiments herein enable improved TIM thermal characteristics and reduced warpage in package structures utilizing the embodiments herein described.

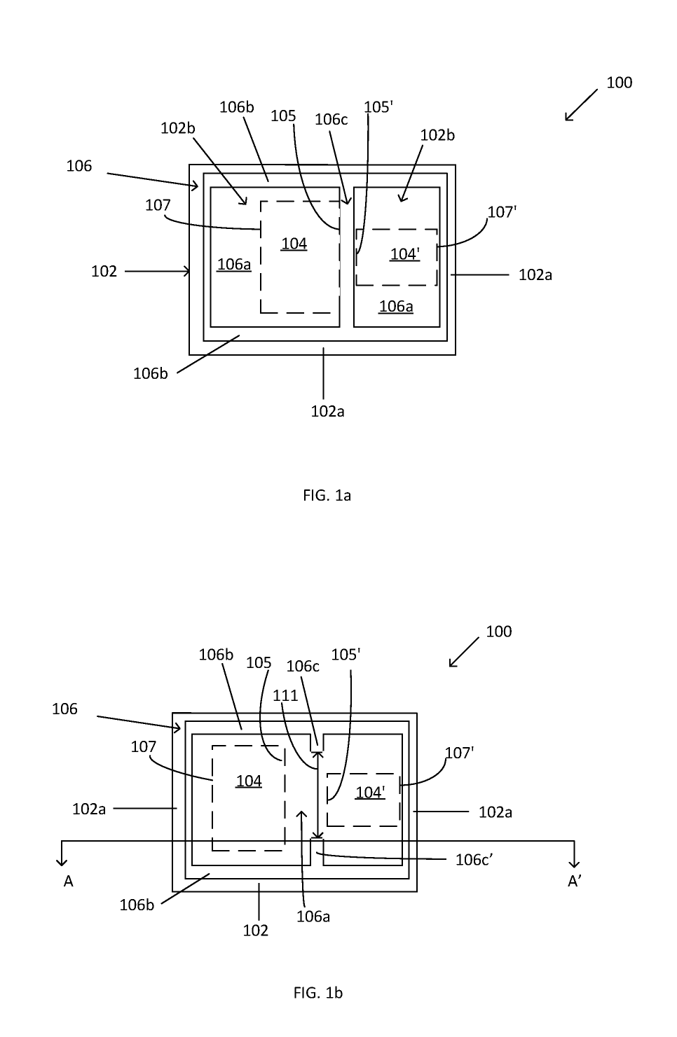

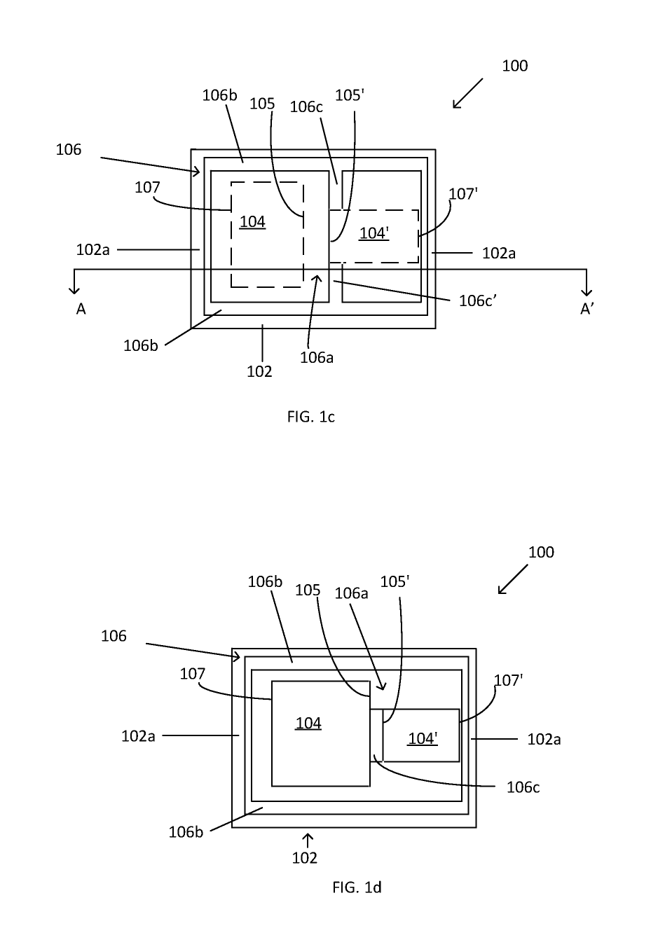

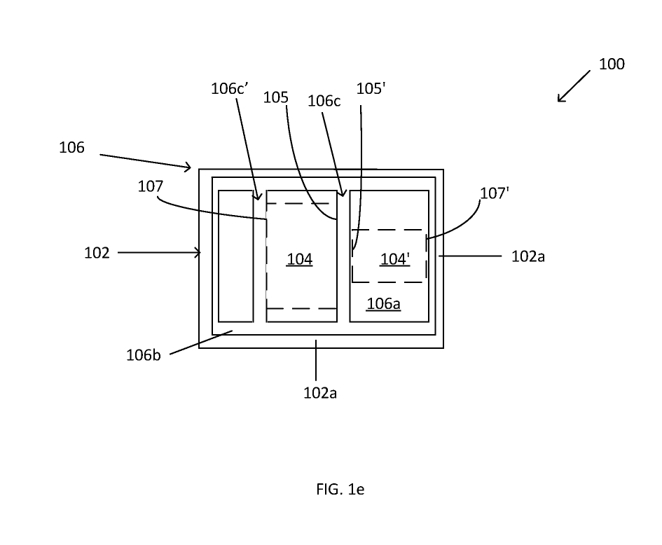

The Figures herein illustrate embodiments of fabricating package structures/modules comprising a cooling solution, such as an integrated heat spreader (IHS), which includes a rib structure for reduction of stress and warpage within a microelectronic package. FIG. 1a depicts a top view of a package structure 100 that may be fabricated according to embodiments included herein. In an embodiment, the package structure may comprise multiple die, and may comprise a multichip package structure 100. The package structure 100 may comprise a substrate 102, which may comprise any suitable substrate 102 that may be utilized to attach at least one device/die thereto. The substrate 102 may comprise a peripheral region 102a. The peripheral region 102a of the substrate 102 may comprise a region proximate to the edges of the substrate 102. In an embodiment, a central region 102b of the substrate 102 may comprise regions of the substrate 102 located closer to a central portion of the substrate 102, away from the edges of the substrate 102, and may be disposed beneath at least one die.

In an embodiment, a first die 104 and a second die 104′ may be disposed within the central portion 102b of the substrate 102. A first die 104 and a second die 104′ may be disposed adjacent one another on a top surface 103 of the substrate 102, and in some embodiments, may comprise different heights. The first and second die 104, 104′ may comprise any type of microelectronic device/functionality, including devices comprising wireless capabilities, such as but not limited to a microprocessor, a graphics processor, a signal processor, a network processor, a chipset, memory devices, platform controller hub (PCH), DRAM memory, graphics processing unit (GPU) and/or field programmable gate array (FPGA) devices, for example. etc. In an embodiment, the package structure 100 may comprises any number of die may be attached to the substrate 102.

In an embodiment, the die 104, 104′ may each comprise a system on a chip (SOC) having multiple functional units (e.g., one or more processing units, one or more graphics units, one or more communications units, one or more signal processing units, one or more security units, etc.). However, it should be understood that the disclosed embodiments are not limited to any particular type or class of die/devices. The first die 104 may comprise a first sidewall 105 and a second sidewall 107, and similarly the second die 104′ may comprise a first and second sidewall 105′, 107′. In an embodiment, the die 104, 104′ may comprise an active side and an opposing back side, wherein a TIM material (not shown) may be disposed on each of the backsides of the die 104, 104′. The active side of the die 104, 104′ may be disposed on the substrate 102.

A cooling solution 106 may be disposed on/over the die 104, 104′ and on/over the substrate 102. The cooling solution 106 may comprise any suitable cooling solution/heat spreader and/or lid 106, and may comprise any suitable thermally conductive materials, and may have any suitable shape or structure. According to one embodiment, the cooling solution 106 may comprise an integrated heat spreader, or IHS. Materials that may be used to construct the cooling solution 106 include metals (e.g., copper and alloys thereof), thermally conductive composites, and thermally conductive polymers. In one embodiment, a wetting layer (e.g., nickel) or other coating may be disposed over at least a portion of the heat spreader's surface.

In an embodiment, the cooling solution/structure 106 may comprise a surface 106a that may comprise a portion of the cooling solution 106 that may be planar, and may be located for the most part, in a non-peripheral region of the substrate 102. The surface 106a of the cooling solution 106 may be disposed, at least partially, over the first and the second die 104, 104′, in an embodiment. In an embodiment, the cooling structure 106 may further comprise a peripheral region/support structures 106b. In an embodiment, the support structures 106b may be located in a peripheral/edge region of the cooling solution 106 and may extend from the planar portion/surface 106a to the substrate 102. In an embodiment, the peripheral region 106b of the cooling solution 106 may comprise support legs/structures that may be attached to the peripheral portions 102a of the substrate 102, and in some cases may be attached/bonded to the substrate 102 by a sealant material, such as an adhesive material, which may comprise polymer and/or epoxy material.

In an embodiment, a rib portion/section 106c of the cooling solution 106 may be disposed between the first and second die 104, 104′, and may be disposed between TIM materials disposed on the backsides of the die 104, 104′, and may extend from the first surface 106a of the cooling solution 106 to the substrate 102. The rib portion 106c of the cooling solution 106 may comprise the same material as the first surface 106a and support structures 106b, and in other embodiments may comprise a different material(s) than the surface 106a and support structures 106b of the cooling solution 106. In an embodiment, the rib/rib portion 106c of the cooling solution 106 may serve to provide thermal support and structural integrity between the TIM materials of the die 104, 104′, such that stresses and thermal degradation are reduced between the die 104, 104′.

For example, by utilizing the rib 106c of the cooling solution 106, a junction resistance between the die 104, 104′ is greatly reduced. In an embodiment, the rib 106c may be disposed on the surface of the substrate 102, and may be physically coupled/bonded to the substrate 102 by a sealant material. The use of the cooling solution including the rib structure 106c serves to reduce sealant to die overhang, and thereby decreases warpage and TIM stress at the corner regions and off-center regions of the die 104, 104′.

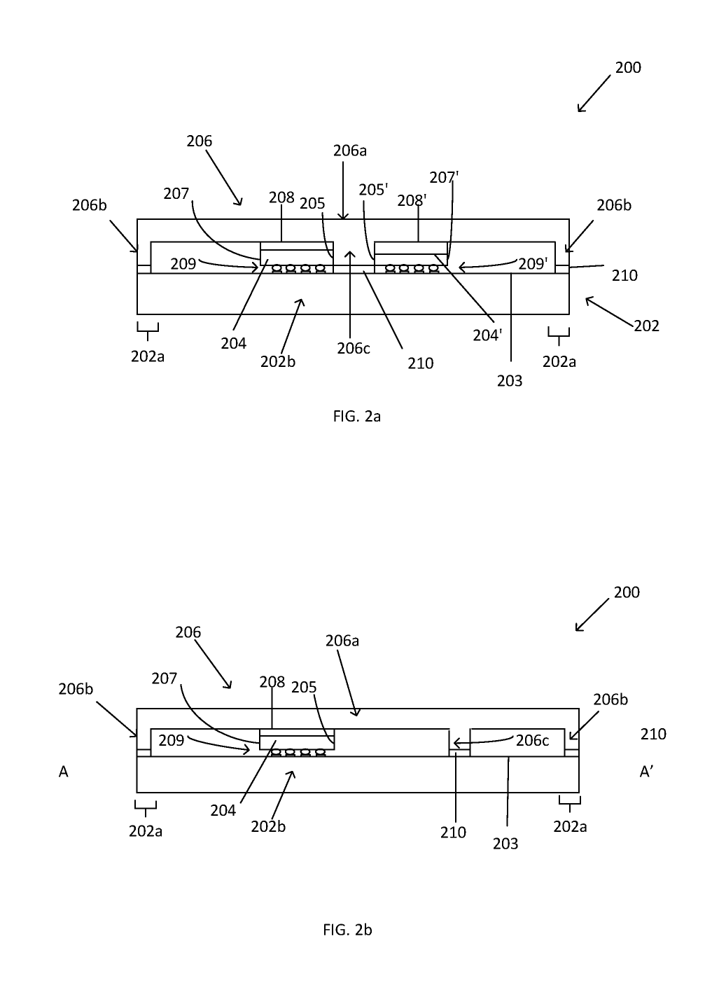

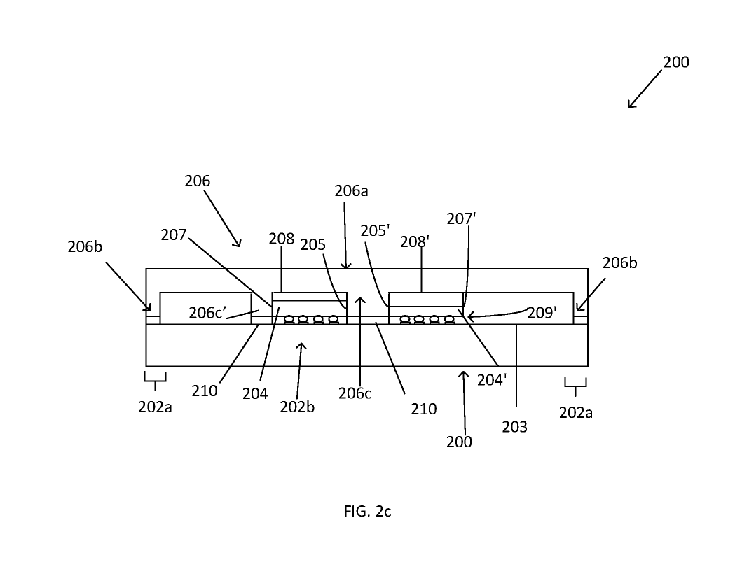

In an embodiment, the rib 106c may be disposed between opposing sides of the peripheral region 106b of the cooling solution 106. In an embodiment, the rib 106c may be continuous between the opposing sides of the cooling solution, and may extend across a portion of the substrate 102, and may be disposed along the first sidewalls 105, 105′ of the die 104, 104′. FIG. 2a depicts a cross sectional view of a package structure 200, which is similar to the package structure 100 of FIG. 1a, for example. The package structure 200 comprises a substrate 202, which includes a peripheral portion 202a and a center portion, non-peripheral portion 202b. A first die 204 and a second die 204′ are disposed on a top surface 203 of the center portion 202b of the substrate 202. Solder interconnect structures 209, 209′ may be disposed between the die 204, 204′ respectively, and the substrate 202. In an embodiment, the solder interconnect structures may comprise first level interconnect structures (FLI).

The first and second die 204, 204′ may comprise first sidewalls 205, 205′ and second sidewalls 207, 207′ respectively, and may comprise different heights from each other. A first thermal interface material (TIM) 208 may be disposed on a backside of the first die 204, and a second TIM 208′ may be disposed on the backside of the second die 204′, and in some embodiment, the thicknesses of the TIM 208, 208′ may comprise different thicknesses from each other. The TIM 208, 208′ may comprise a material that serves to provide thermal conductivity between the die 204, 204′ and the cooling solution 206. In an embodiment, the TIM material may comprise a polymer material, or any other suitable material depending upon the particular design requirements. The TIM 214 may serve to thermally couple the die 206, 206′ with a cooling solution, and may comprise any suitable thermally conductive material capable of forming a thermally conductive (and perhaps mechanical) bond between the backsides of the die 204, 204′ and a cooling solution. For example, the TIM material may comprise a solder material, a composite material, a thermally conductive polymer, as well as any combination of these and/or other materials.

In one embodiment, a planar portion/surface 206a of the cooling solution 206 may be disposed on/over the first and second die 204, 204′, and may be disposed on a surface of the first and second TIM 208, 208′, in an embodiment. The peripheral portions/support structures 206b of the cooling solution 206 may extend from the surface 206a to edges/peripheral portions 202a of the substrate 202, and may be bonded to the peripheral portion of the substrate 202a with a sealant 210. The rib/rib structure 206c of the cooling solution 206 may be disposed between the first die 204 and the second die 204′, and may be adjacent the first sidewalls 205, 205′ of the first and second die 204, 204′. In an embodiment, the rib 206c may extend from the surface 206a of the cooling solution 206 to the center portion 202b of the substrate 202, and may be adjacent, and in between, the peripheral portion 206b. The rib 206c may serve to reduce stress between the die 204, 204′, and may reduce TIM degradation by providing mechanical and thermal support between the die 204, 204′. The rib 206c serves to reduce warpage and junction resistance between the die 204, 204′. In an embodiment, the rib 206c may be bonded to the substrate 202 with a sealant material 210.

In another embodiment, referring to FIG. 1b (top view), rib portions/section(s) 106c, 106c′ of the cooling solution 106 may extend partially between opposing sides of the peripheral region 106b of the cooling solution 106, and may be discontinuous between opposing sides of the peripheral region 106b. In an embodiment, the rib portions 106c, 106c′ may extend only partially across the substrate 102, and there may be a gap 111 between rib portions 106c, 106c′. The discontinuous rib portions 106c, 106c′ may provide thermal stress reduction by virtue of their proximity to the die 104, 104′. In an embodiment, the rib portions 106c, 106c′ may not be adjacent the first die 104 and/or the second die 104′ sidewalls. The rib portions 106c, 106c′ may be disposed on/attached to the substrate 102, within the center region 102b, and may be bonded to a surface of the substrate 102 by a sealant disposed between the rib portions 106c, 106c′ and the substrate 102. The line between points A and A′ is a line through the die 104 and the rib portion 106c′.

In another embodiment, a package structure 100 (top view), similar to the package structure of FIG. 1b, may comprise rib portions 106c, 106c′ that may be discontinuous between peripheral portions 106b, and may extend from the planar surface 106a of the cooling solution 106 to the substrate (FIG. 1c). The rib portions 106c, 106c′ may be directly disposed on a portion of the die sidewalls, such as on a portion of the first sidewall 105′ of the second die 104′, as well as on the edges of the die 104′ (FIG. 1c). The die 104′ may be located between the rib portions 106c, 106c′. The rib portions 106c, 106c′ provide structural stability and decrease warpage at stress sites between die. The line between points A and A′ is a line through the die 104 and the rib portion 106c′.

FIG. 2b depicts a cross sectional view through the line A-A′ which includes the discontinuous rib portions, such as those depicted in FIGS. 1b-1c. The package structure 200 comprises a substrate 202, which includes a peripheral portion 202a and a central, non-peripheral portion 202b. A first die 204 and a second die (not shown) may be disposed on a top surface 203 of the central portion 202b of the substrate 202. Although two die are referred to in embodiments, any number of die may be disposed within the package substrate 200 (or in any of the package structure embodiments described herein), in some embodiments. Solder interconnect structures 209 may be disposed between the die 204 and the substrate 202. The first die 204 may comprise a first sidewall 205 and a second sidewall 207. A thermal interface material (TIM) 208 may be disposed on a backside of the first die 204.

In one embodiment, a planar surface/portion 206a of the cooling solution 206 may be disposed on/over the first die 204, and may be disposed on a surface of the TIM 208. The peripheral portions/support portions 206b of the cooling solution 206 may be disposed on/attached to the edges/peripheral portions 202a of the substrate 202. The rib 206c may be disposed adjacent the first die 204, and may be adjacent the first sidewall 205. In other embodiments, the rib portion 206c of the cooling solution 206 may be adjacent the second sidewall 207. The rib 206c (only one is shown) may serve to reduce stress between the die 204, and a second die (not shown), and may reduce TIM 208 degradation by providing mechanical and thermal support between the die. The rib 206c serves to reduce warpage and junction resistance between the die. In an embodiment, the rib 206c may be bonded to the substrate 202 with a sealant material 210.

In another embodiment (referring to FIG. 1d), a package structure 100 (top view), similar to the package structure of FIG. 1b, for example, may comprise a rib 106c, that may be disposed, and in some cases directly disposed, on at least portions of the sidewalls 105, 105′ of the die 104, 104′, and may be disposed between the first die and the second die 104, 104′. The rib 106c may be disposed between the first and the second TIM materials/layers disposed on the die 104, 104′. The rib 106c serves to reduce thermal and mechanical stress between the die 104, 104′ that may lead to failures, including warpage failures, in the package structure 100. The rib 106c of the cooling solution 106 may be discontinuous with the peripheral portion 106b, and may or may not comprise similar or the substantially the same materials as the rest of the portions of the cooling solution 106. The rib 106c of FIG. 1d may extend from the surface 106a of the cooling solution to the substrate 202, and may be disposed/bonded to the substrate 102 in a central portion 102a, by a sealant material.

In another embodiment, a second rib 106c′ may be disposed adjacent either one of the second sidewalls 107, 107′ of the first die 104 or the second die 104′, and may further provide stress relief and reduce warpage in the package structure 100 (FIG. 1e). The second rib 106c′ may be located between opposing sides of the peripheral portion 106b of the cooling solution 106, and may fully extend between the opposing sides, and may comprise a continuous rib 106c′. The second rib 106c′ may extend from the planar portion 106a to the substrate 102, and may be attached/bonded to the substrate 102, in the central substrate region 102b, by a sealant. FIG. 2c depicts a cross-sectional view of the package structure of FIG. 1e, wherein the first rib 206c and the second rib 206c′ are attached on the substrate 202a by a sealant material 210.

The package structure 200 comprises a substrate 202, which includes a peripheral portion 202a and a central, non-peripheral portion 202b. A first die 204 and a second die 204′ are disposed on a top surface 203 of the central portion 202b of the substrate 202, adjacent each other. The first and second die 204, 204′ may comprise first sidewalls 205, 205′ and second sidewalls 207, 207′ respectively and may include solder interconnect structures 209, 209′ disposed between the die 204, 204′ and the substrate 202, respectively. A first thermal interface material (TIM) 208 may be disposed on a backside of the first die 204, and a second TIM 208′ may be disposed on the backside of the second die 204′.

The planar portion 206a of the cooling solution 206 may be disposed on/over the first and second die 204, 204′, and may be disposed on a surface of the first and second TIM 208, 208′, in an embodiment. The peripheral portions 206b of the cooling solution 206 may be disposed on the edges/peripheral portions 202a of the substrate 202, and may be bonded to the peripheral portion of the substrate 202a with sealant 210. The first rib portion 206c may be disposed between the first die 204 and the second die 204′, and may be adjacent the first sidewalls 105, 105′ of the first and second die 204, 204′. In an embodiment, the first rib 206c and the second rib 206c′ may be bonded to the substrate 202 with a sealant material 210.

In some embodiments, a heat sink (or other cooling device, not shown) may be thermally coupled with the cooling solution of the various embodiments, and another layer of a thermal interface material may be disposed between the cooling solution the heat sink (or other device). By way of example, the heat sink may comprise a multi-fin (or multi-pin) heat sink secured over the cooling solution and die by a retention mechanism.

The various embodiments of the package assemblies/interconnect structures according to the embodiments herein describe the fabrication of various cooling structures for stress reduction and improvement of thermal properties for such package structures. Complex multi-chip packages, which may include multiple chips disposed on a single substrate within the package, may experience die to die height variations that in turn result in differing TIM heights. Warpage for a multi-chip package may be significantly higher than for single chip packages. Higher warpage, such as dynamic warpage, can result in TIM stress and degradation, which effects yields.

By providing the rib structures of the cooling solutions described herein, TIM stress and degradation is reduced, thus increasing TIM lifetime. Stress within the TIM at corners of the die, as well as stresses due to die to die interfaces, are significantly removed by incorporating the structures and methods described herein. The use of the rib structures in the cooling solution reduces sealant to die overhang, and thereby decreases warpage and TIM stress at the corner regions and off-center regions of the die.

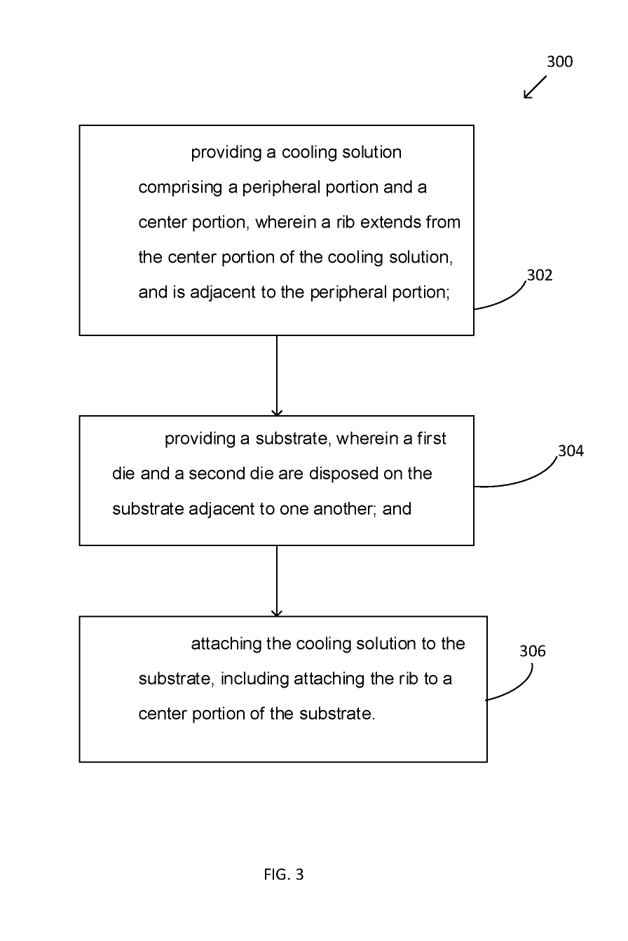

FIG. 3 depicts a method 300 of forming a package structure according to embodiments herein. At step 302, a cooling solution is provided comprising a peripheral portion and a center portion, wherein a rib extends from the center portion of the cooling solution, and is adjacent to the peripheral portion. In an embodiment, the cooling solution may further comprise a peripheral portion. The rib may be disposed at least partially within the center portion of the cooling solution, and is adjacent to the peripheral portion. In an embodiment, the cooling solution may comprise an integrated heat spreader. In an embodiment, the rib may comprise a discontinuous, or a continuous rib between opposite sides of the peripheral portion of the cooling solution. At step 304, a substrate may be provided, wherein a first die and a second die are disposed on the substrate adjacent to one another. In an embodiment, the substrate may comprise a portion of a multi-die package structure, and more than two die may be disposed on the substrate.

At step 306, the cooling solution may be attached to the substrate, including attaching the rib to a center portion of the substrate. The rib may be disposed between the first die and the second die, in an embodiment. In other embodiments, the rib portion may be disposed adjacent sidewalls of the first and/or the second die and may not be between both die, and in some embodiments, a second rib may be disposed adjacent the first rib.

The structures of the embodiments herein may be coupled with any suitable type of structures capable of providing electrical communications between a microelectronic device, such as a die, disposed in package structures, and a next-level component to which the package structures may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, the die(s) may be partially or fully embedded in a package structure.

The various embodiments of the package structures included herein may be used for system on a chip (SOC) products, and may find application in such devices as smart phones, notebooks, tablets, wearable devices and other electronic mobile devices. In various implementations, the package structures may be included in a laptop, a netbook, an ultrabook, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

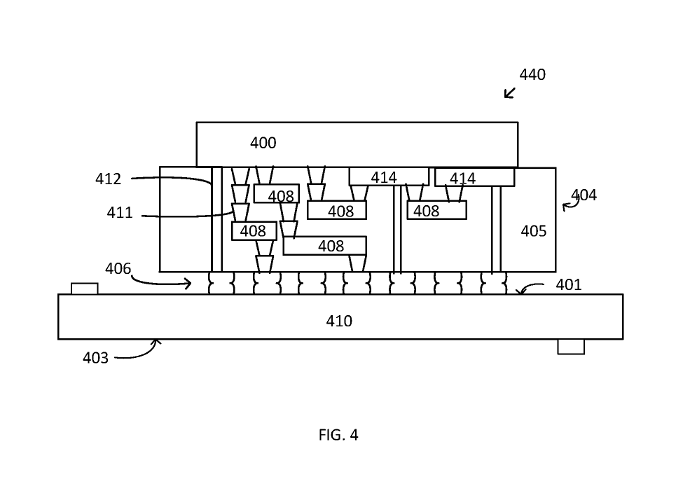

Turning now to FIG. 4, illustrated is a cross sectional view of an embodiment of a computing system 440. The system 440 includes any number of components disposed on a mainboard 410 or other circuit board. Mainboard 410 includes a first side 401 and an opposing second side 403, and various components may be disposed on either one or both of the first and second sides 401, 403. In the illustrated embodiment, the computing system 440 includes a package structure 400 disposed on the mainboard's first side 401, wherein the package structure 400 may comprise any of the package structures including the cooling structures described herein according to embodiments, such as the package structure 100 of FIG. 1a, for example. System 440 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

Mainboard 410 may comprise any suitable type of circuit board or other substrate capable of providing electrical communication between one or more of the various components disposed on the board. In one embodiment, for example, the mainboard 410 comprises a printed circuit board (PCB). However, it should be understood that the disclosed embodiments are not limited to the above-described PCB and, further, that mainboard 410 may comprise any other suitable substrate.

In an embodiment, a substrate 404, such as an interposer, for example, may be disposed between the package structure 400 and the board 410, and may be physically and electrically coupled with the board by interconnect structures 406. The substrate 404 may comprise multiple metal layers 408, such as layers 408 that may be electrically coupled with vias 411, wherein the metal layers may be separated from one another by a layer(s) of dielectric material, such as dielectric layer 405. The substrate 404 may further comprise conductive through hole vias 412 and conductive pads 414 disposed on one or more surfaces of the substrate 404.

In an embodiment, any one or more of the conductive structures 412, 408, 411, 414 may be formed in a desired circuit pattern to route—perhaps in conjunction with other metal layers—electrical signals between the package structure 400 and the board 410. In another embodiment, the package structure 400 may be directly attached/electrically and physically coupled to the mainboard 410, by a substrate included within the package structure 440, such as the substrate 102 of FIG. 1, for example, and wherein the substrate 102 may comprise the same or similar elements as the substrate 404. In addition to the package structure 400, one or more additional components may be disposed on either one or both sides 401, 403 of the mainboard 410.

The additional components may include other IC devices (e.g., processing devices, memory devices, signal processing devices, wireless communication devices, graphics controllers and/or drivers, audio processors and/or controllers, etc.), power delivery components (e.g., a voltage regulator and/or other power management devices, a power supply such as a battery, and/or passive devices such as a capacitor), and one or more user interface devices (e.g., an audio input device, an audio output device, a keypad or other data entry device such as a touch screen display, and/or a graphics display, etc.), as well as any combination of these and/or other devices. In one embodiment, the computing system 440 includes a radiation shield.

In a further embodiment, the computing system 440 may include a cooling device disposed on the package structure 400, such as a heat sink, that may be disposed on a cooling solution described in the embodiments herein. In yet another embodiment, the computing system 440 includes an antenna. In yet a further embodiment, the assembly 440 may be disposed within a housing or case. Where the mainboard 410 is disposed within a housing, some of the components of computer system 440—e.g., a user interface device, such as a display or keypad, and/or a power supply, such as a battery—may be electrically coupled with the mainboard 410 (and/or a component disposed on this board) but may be mechanically coupled with the housing.

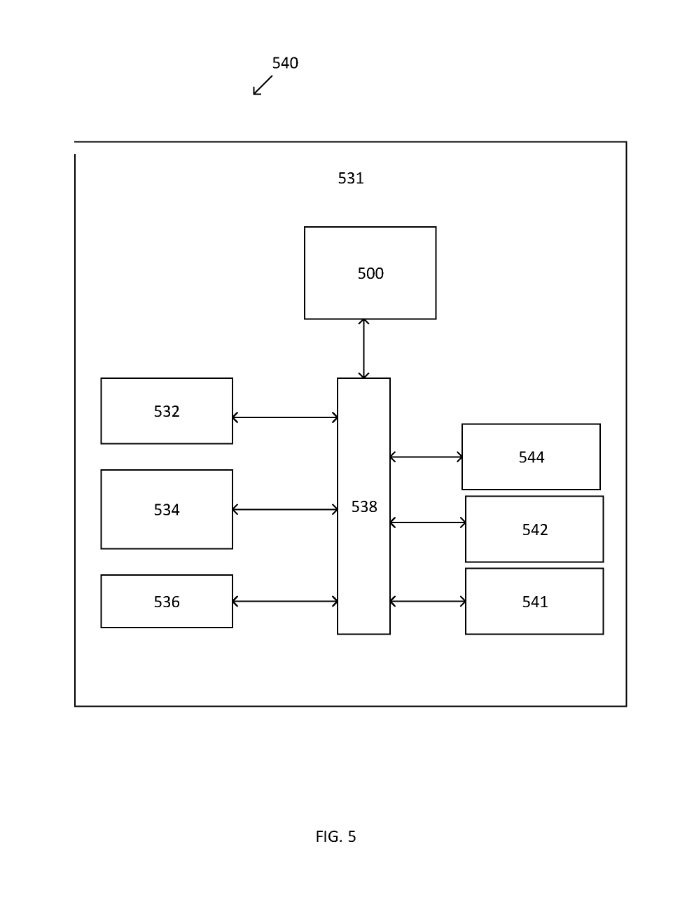

Turning now to FIG. 5, illustrated is a schematic of an embodiment of a portion of a computing system 540, including one or more of the package structures 500, fabricated according to any of the embodiments of the package structures included herein, such as package structure 100 of FIG. 1a. The package structure 500 may include any or all of the elements of the embodiments included herein as a part of the system 540.

In some embodiments, the system 540 includes a processing means such as one or more processors 532 coupled to one or more buses or interconnects, shown in general as bus 538. The processors 532 may comprise one or more physical processors and one or more logical processors. In some embodiments, the processors may include one or more general-purpose processors or special-processor processors.

The bus 538 may be a communication means for transmission of data. The bus 538 may be a single bus for shown for simplicity, but may represent multiple different interconnects or buses and the component connections to such interconnects or buses may vary. The bus 538 shown in FIG. 5 is an abstraction that represents any one or more separate physical buses, point-to-point connections, or both connected by appropriate bridges, adapters, or controllers. In some embodiments, the system 540 further comprises a random access memory (RAM) or other dynamic storage device or element as a main memory 534 for storing information and instructions to be executed by the processors 532. Main memory 534 may include, but is not limited to, dynamic random access memory (DRAM). The system 540 also may comprise one or more passive devices 536, such as capacitors and inductors that may be installed on a board, such as a printed circuit board 531.

In some embodiments, the system 540 includes one or more transmitters or receivers 541 coupled to the bus 538. In some embodiments, the system 440 may include one or more antennae 544 (internal or external), such as dipole or monopole antennae, for the transmission and reception of data via wireless communication using a wireless transmitter, receiver, or both, and one or more ports 542 for the transmission and reception of data via wired communications. Wireless communication includes, but is not limited to, Wi-Fi, Bluetooth™, near field communication, and other wireless communication standards. In an embodiment an antenna may be included in the module 500.

System 540 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

### EXAMPLES

Example 1 is a microelectronic package structure comprising: a first die disposed on a substrate; a second die disposed adjacent the first die on the substrate; a cooling solution comprising: a planar portion disposed at least partially over the first die and the second die; a peripheral portion extending from the planar portion and attached to a peripheral portion of the substrate; and a rib, wherein the rib comprises a first rib, and wherein the rib extends from the planar portion and is attached to a central portion of the substrate.

Example 2 includes the microelectronic package structure of example 1 wherein the cooling solution comprises an integrated heat spreader.

Example 3 includes the microelectronic package structure of any of the examples 1-2 wherein a first thermal interface material (TIM) is disposed on a backside of the first die, wherein the backside of the first die is opposite an active side of the first die, and a second TIM is disposed on a backside of the second die, wherein the backside of the second die is opposite an active side of the second die, and wherein the rib is disposed between the first TIM and the second TIM.

Example 4 includes the microelectronic package structure of any of the examples 1-3 wherein a sealant is disposed between the rib and the substrate.

Example 5 includes the microelectronic package structure any of examples 1-4 wherein the rib is continuous between opposite sides of the peripheral portion.

Example 6 includes the microelectronic package structure of any of the examples 1-5 wherein the cooling solution comprises a second rib, wherein one of the first die or the second die is disposed between the first rib the peripheral portion of the cooling solution.

Example 7 includes the microelectronic package structure of any of the examples 1-6 wherein the rib is discontinuous between opposite sides of the peripheral portion.

Example 8 includes the microelectronic package structure of example 7 wherein the rib is disposed on a portion of one of the first or second die.

Example 9 includes the microelectronic package structure of example 7 wherein the rib is disposed between the first die and the second die.

Example 10 is a microelectronic package structure comprising: a first die disposed on a substrate; a second die disposed on the substrate, adjacent the first die; a first TIM disposed on a back side of the first die; a second TIM disposed on a backside of the second die; and a cooling solution disposed on the first TIM and on the second TIM, wherein the cooling solution comprises a first rib extending from the cooling solution and attached to a central portion of the substrate.

Example 11 includes the microelectronic package structure of example 10 wherein a sealant is disposed between the first rib and the substrate.

Example 12 includes the microelectronic package structure of any of examples 10-11 wherein the first rib is disposed between a first sidewall of the first die and a first sidewall of the second die.

Example 13 includes the microelectronic package structure of example 12 wherein a second rib is disposed on a second sidewall of the first die.

Example 14 includes the microelectronic package structure of any of the examples 10-13 wherein the first rib and a peripheral portion of the cooling solution comprise the same material.

Example 15 includes the microelectronic package structure of any of the examples 10-14 wherein the first rib is disposed between the first TIM and the second TIM.

Example 16 includes the microelectronic package structure of any of the examples 10-15 wherein at least one of the first rib or the second rib is continuous between opposite sides of a peripheral portion of the cooling solution.

Example 17 includes the microelectronic package structure of any of the examples 10-16, wherein the first rib is discontinuous between opposite sides of a peripheral portion of the cooling solution.

Example 18 is a method of forming a microelectronic package comprising: providing a cooling solution comprising a peripheral portion and a center portion, wherein a rib extends from the center portion of the cooling solution, and is adjacent to the peripheral portion; providing a substrate, wherein a first die and a second die are disposed on the substrate adjacent to one another; and attaching the cooling solution to the substrate, including attaching the rib to a central portion of the substrate.

Example 19 includes the method of example 18 wherein attaching the rib to the central portion comprises attaching the rib onto the substrate between the first die and the second die.

Example 20 includes the method of any of the examples 18-19 wherein a backside of the first die comprises a first TIM, and a backside the second die comprises a second TIM, wherein attaching the rib comprises attaching the rib between the first TIM and the second TIM on the substrate.

Example 21 includes the method of any of the examples 18-20 wherein a height of the first die is different from a height of the second die.

Example 22 includes the method of any of the examples 18-21 further comprising attaching the rib and the peripheral portion to the substrate with a sealant.

Example 23 includes the method of any of the examples 18-22 wherein the rib is continuous between opposite sides of the peripheral portion of the cooling solution.

Example 24 includes the method of any of the examples 18-23 wherein the rib is discontinuous between opposite sides of the peripheral section.

Example 25 includes the method of any of the examples 18-24 wherein the cooling solution further comprises a second rib adjacent the first rib section, wherein one of the first die or the second die is disposed between the first rib and the second rib.

Example 26 is a computing system comprising: a processor for processing data; a memory for storage of data; a transmitter or receiver for transmission and reception of data; and a module including: a package disposed on a board and coupled to the memory, wherein the package comprises: a first die disposed on a substrate; a second die disposed on the substrate; a cooling solution disposed on the first and second die, wherein the cooling solution comprises: a peripheral portion attached to a peripheral portion of the substrate; and a rib extending from a center portion of the cooling solution and attached to a central portion of the substrate.

Example 27 includes the system of examples 26 wherein the rib is disposed between a first sidewall of the first die and a first sidewall of the second die.

Example 28 includes the system of any of the examples 26-27 wherein the rib comprises a first rib, and a second rib is disposed on a second sidewall of the first die.

Example 29 includes the system of any of the examples 26-27 wherein the rib and the peripheral portion comprise the same material.

Example 30 includes the system of any of the examples 26-27 wherein the rib is disposed between a first TIM and a second TIM, wherein the first TIM is disposed on the first die and the second TIM is disposed on the second die.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus, the embodiments are not limited to the structures described herein.

1. A microelectronic package structure comprising:
a first die on a substrate;
a second die adjacent the first die on the substrate;
a cooling solution comprising:
a planar portion at least partially over the first die and the second die;
a peripheral portion of the cooling solution extending from the planar portion and attached to a peripheral portion of the substrate; and
a rib extending from the planar portion and attached to a central portion of the substrate, wherein the rib is directly on a portion of a sidewall of at least one of the first die or the second die.

2. The microelectronic package structure of claim 1 wherein the cooling solution comprises an integrated heat spreader.

3. The microelectronic package structure of claim 1 wherein a first thermal interface material (TIM) is on a backside of the first die, wherein the backside of the first die is opposite an active side of the first die, and a second TIM is on a backside of the second die, wherein the backside of the second die is opposite an active side of the second die, and wherein the rib is between the first TIM and the second TIM, wherein a thickness of the first TIM is different than a thickness of the second TIM, and wherein the rib is directly on the first TIM and is directly on the second TIM.

4. The microelectronic package structure of claim 1 wherein a sealant is between the rib and the substrate.

5. The microelectronic package structure of claim 1 wherein the rib is continuous between opposite sides of the peripheral portion of the cooling solution.

6. The microelectronic package structure of claim 1 wherein the cooling solution comprises a second rib, wherein the second rib is disposed between one of the first die or the second die and the peripheral portion of the cooling solution.

7. The microelectronic package structure of claim 1 wherein the rib is discontinuous between opposite sides of the peripheral portion.

8. The microelectronic package structure of claim 7 wherein the rib is disposed on a portion of one of the first or the second die.

9. The microelectronic package structure of claim 7 wherein the rib is disposed between the first die and the second die.

10. A microelectronic package structure comprising:
a first die on a substrate;
a second die on the substrate, adjacent the first die;
a first TIM on a back side of the first die;
a second TIM on a backside of the second die; and
a cooling solution on the first TIM and on the second TIM, wherein the cooling solution comprises a rib extending from a surface of the cooling solution, wherein the rib is attached to a central portion of the substrate, and wherein the rib is directly on at least one of the first TIM or the second TIM.

11. The microelectronic package structure of claim 10 wherein a sealant is between the rib and the substrate.

12. The microelectronic package structure of claim 10 wherein the rib is between and is directly on a first sidewall of the first die and is directly on a sidewall of the second die.

13. The microelectronic package structure of claim 12 wherein a second rib extends from the cooling solution to a central portion of the substrate, wherein the second rib is disposed ona second sidewall of the first die.

14. The microelectronic package structure of claim 13 wherein the first rib and the second rib comprise the same material.

15. The microelectronic package structure of claim 10 wherein the rib is between the first TIM and the second TIM.

16. The microelectronic package structure of claim 10 wherein at least one of the first rib or the second rib is continuous between opposite sides of a peripheral portion of the cooling solution.

17. The microelectronic package structure of claim 10, wherein the first rib is discontinuous between opposite sides of a peripheral portion of the cooling solution.

18. A method of forming a microelectronic package comprising:
providing a cooling solution comprising a peripheral portion and a center portion, wherein a rib extends from the center portion of the cooling solution, and is adjacent to the peripheral portion;
providing a substrate, wherein a first die and a second die are disposed on the substrate adjacent to one another; and
attaching the cooling solution to the substrate, including attaching the rib to a central portion of the substrate.

19. The method of claim 18 wherein attaching the rib to the central portion comprises attaching the rib onto the substrate between the first die and the second die.

20. The method of claim 18 wherein a backside of the first die comprises a first TIM, and a backside the second die comprises a second TIM, wherein attaching the rib comprises attaching the rib between the first TIM and the second TIM onto the substrate.

21. The method of claim 18 wherein a height of the first die is different than a height of the second die.

22. The method of claim 18 further comprising attaching the rib to the substrate with a sealant.

23. The method of claim 18 wherein the rib is continuous between opposite sides of a peripheral portion of the cooling solution.

24. The method of claim 18 wherein the rib is discontinuous between opposite sides of a peripheral section of the cooling solution.

25. The method of claim 18 wherein the cooling solution further comprises a second rib adjacent the first rib, wherein one of the first die or the second die is disposed between the first rib and the second rib.
